(19) United States
(12) Patent Application Publication
(10) Pub. No.: US 2005/0259049 A1
(43) Pub. Date: Nov. 24, 2005

(54) Organic electroluminescent display structure

(76) Inventor: Kuang-Jung Chen, Taipei City (TW)

Correspondence Address: RABIN & Berdo, PC, 1101 14TH STREET, NW, SUITE 500, WASHINGTON, DC, 20005, US

(21) Appl. No.: 11/105,530

(22) Filed: Apr. 14, 2005

(30) Foreign Application Priority Data
May 4, 2004 (TW) 93112498

(51) Int. Cl. G09G 3/30

(52) U.S. Cl. 345/76

(57) ABSTRACT

An organic electroluminescent display (OEL) structure is utilized the UV light as a light source. The light is converted into three original colors of red, green, and blue lights through the fluorescent color conversion layer, so as to be able to eliminate the additional color filtering layer and raise light conversion efficiency. As such, an active substrate, a fluorescent color conversion layer, a UV light emission layer and a encapsulation layer are combined to form the full color active organic electroluminescent display structure, which can be mass produced by utilizing the existing manufacturing process and equipment, thus achieving the purpose of reducing the production cost.

### BACKGROUND

1. Field of the Invention

The invention relates to an organic electroluminescent display structure, especially to a full color active organic electroluminescent display structure of ultraviolet (UV) light color conversion.

2. Related Art

The organic electroluminescent (OEL or Organic Light Emitting Diode (OLED)) display has been considered as the most promising flat panel display technology product for the next generation, due to its capabilities of self-lumination, wide viewing angle, superior resolution, and high illuminescence. Therefore, presently the major manufacturing companies in the industrialized countries have dedicated their efforts in the research and development of the OEL technology.

In the application of the OEL technology, the full color displaying capability is essential to its market success. When it is classified according to color formation, the organic electroluminescent display (OEL) is mainly composed of the following three structures: the 3-color light emitting layer structure, the color conversion structure, and the color filter structure. The 3-color light-emitting layer structure is the most frequently used structure in the full color organic electroluminescent display (OEL). Its main features consist of applying the red, blue, and green light emitting materials on the pixels respectively, then applying different voltages on them to create a full color effect. The advantage of this technology is that its light emission efficiency can be optimized. However, it suffers from shortcomings and drawbacks: it is not easy to mass produce the red, blue, and green colors. Because the red, blue, and green colors are produced from three different materials, the design of its driving circuit is much more complicated. And because the life spans of the three colors are different, it is rather difficult to control the image quality. With regard to the color conversion structure, blue light is used as a light source. In the color conversion process, blue light is first converted into the red and green lights through the color conversion structure, so as to create red, blue, and green colors. The manufacturing process of this method is much simpler, and having a higher feasibility of mass production. However, when blue light is excited to create red light and green light, it will produce a mixture of lights, such as blue/red light and blue/green light, therefore a color filtering layer is required to filter out the blue light contained in the blue/red light and blue/green light, and thus resulting in the reduction of the conversion efficiency of the blue light to the red light and green light, and constituting a limit of the full color conversion using the blue light.

In the application of the color filter structure, the white light producing diode is used to create white light, and then it is transmitted through a color filter to achieve a full color effect. The advantage of full color conversion technology is that the existing color filter technology of liquid crystal display can be utilized directly. Yet in the light emitting process, the emitted light must be transmitted through an additional color filter, thus resulting in the reduction of a light emitting efficiency. Since the technology of producing a full color display through color conversion, the preparation and manufacturing of the light emitting materials is still under consistent research and development. If the service lives and the light emitting efficiencies of such light emitting materials can reach a sufficient level, the mass production of the full color organic electroluminescent display using these materials becomes feasible.

In addition, in the full color organic light emitting diode disclosed in Taiwan Patent Publication No. 382878, the UV organic light emitting diode is made of organic ultra violet (UV) light emitting material, and a plurality of UV light emitting diodes are arranged into a plurality of matrix shape light emitting pixels, and a layer of fluorescent material of red, green and blue colors are coated respectively onto the surface of each of the light emitting pixel. When the fluorescent material layer is excited by UV light, it produces red, green, and blue lights to create a matrix shape full color light emission. The red, green, and blue lights obtained from the fluorescent material layer as excited by the incident UV light could have a relatively good color conversion quality. Meanwhile, there is no need for an additional color filtering layer, thus it is capable of achieving better light conversion efficiency. As such, UV light can be utilized as the ideal light source for color conversion. However, the application of the active matrix OEL and its manufacturing technology are not mature enough. Therefore, a problem of making use of the present technology and the process for developing practical full color active matrix type OEL structure becomes more mad more important to the OEL industry.

### SUMMARY

In view of the above-mentioned problems and shortcomings of the prior art, the object of the invention is to provide an OEL structure, having the benefit of using UV light as the light source for the color conversion structure, so as to achieve the purpose of: high light conversion efficiency, mass production with reduced cost, by utilizing existing manufacturing process and equipment, without requiring an additional color filtering layer.

According to the technology as disclosed by the invention, the combination of a UV light emission layer and a fluorescent color conversion layer is utilized in increasing the light conversion efficiency so that the additional color filtering layer required by the prior art can be eliminated. Wherein the substance of the fluorescent color conversion layer is excited by the energy of the UV light (with its wavelength <400 nm) which is emitted by the UV light emission layer to emit the converted red, green, and blue lights.

The invention provides an OEL structure, comprising a substrate (which may be an active matrix substrate), a fluorescent color conversion layer, a UV light emission layer, and an encapsulation layer. The substrate is provided with a plurality of matrix elements and a plurality of conductive connection points. The conductive connection points are connected to the upper surface of the substrate and are electrically connected to the matrix elements. The fluorescent color conversion layer is composed of a plurality of fluorescent color conversion patterns formed by the red, green, and blue fluorescent color conversion material. The fluorescent color conversion layer can be disposed on the substrate or is directly imbedded therein. The UV light emission layer includes UV light electroluminescent material and is provided with a plurality of electrodes to be used to excite the UV electroluminescent material. The UV light emission layer is formed on the upper surface of the substrate, so that it is electrically connected to the active matrix elements via the conductive connection points. Finally, the encapsulation layer is coated on the surface of the UV light emission layer. In this structure, the light, emitted by the UV light emission layer, is transmitted through the substrate, then transmitted through the fluorescent color conversion layer, and is converted into the red, green, and blue lights. Then it is emitted through the bottom surface of the substrate, so as to realize the light emission of the bottom emission type full color active organic electroluminescent display structure.

In addition, the invention also provides a top emission type full color active organic electroluminescent display structure. It is realized by disposing the above-mentioned fluorescent color conversion layer on top of the UV light emission layer, and the encapsulation layer must be transparent to allow transmission of the light. Furthermore, a plurality of reflection electrodes and transparent electrodes are provided in the UV light emission layer structure, and the reflection electrode is electrically connected to the active matrix element via the conductive connection point. The light emitted from the UV light emission layer is reflected by reflection electrodes, and emitted out of the upper surface of the UV light emission layer. The emitted light is then converted into red, green, and blue lights through the fluorescent color conversion layer, and then emitted through the transparent encapsulation layer, to realize the top emission light.

The purpose, construction, features, and functions of the present invention can be appreciated and understood further through the following detailed description, with reference to the attached drawings.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below illustration only, and thus is not limitative of the present invention, wherein:

FIG. 1 is a schematic diagram illustrating the organic electroluminescent display (OEL) structure according to the first embodiment of the invention;

FIG. 2 is a schematic diagram illustrating the organic electroluminescent display (OEL) structure according to the second embodiment of the invention; and

FIG. 3 is a schematic diagram illustrating the organic electroluminescent display (OEL) structure according to the third embodiment of the invention.

### DETAILED DESCRIPTION

The full color organic electroluminescent display structure (which can be an active type) disclosed by the invention comprises a UV light emission layer, a fluorescent color conversion structure, and a substrate. Wherein, the substrate can be an active matrix substrate, and can be formed by one of the following materials or their combinations: glass, silicon, and plastics, and it is also provided with a plurality of matrix elements (which can be a thin film transistor (TFT)). The UV light emission layer is formed by the UV light electroluminescent material with a wavelength of its emitted light less than 400 nm, which is composed of small molecules, oligomer or polymer organic material. If this UV light electroluminescent material is composed of small molecule organic material, then it can be made by a heat evaporation method and be directly formed on the substrate; or if the mentioned layer is composed of oligomer or polymer organic material, then it can be made by a spin coating or ink jet printing method.

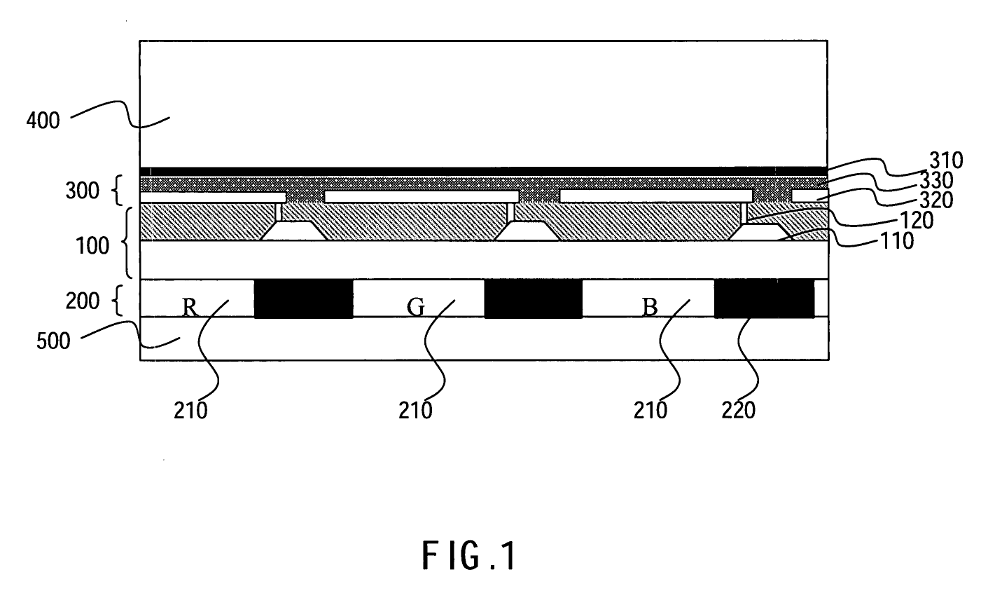

Refer to FIG. 1 for a more detailed description of the structure of the invention, which shows the schematic diagram of the OEL structure according to the first embodiment of the invention. As illustrated, the OEL structure mainly includes a substrate 100 (which can be active matrix), a fluorescent color conversion layer 200, a UV light emission layer 300, an encapsulation layer 400, and a transparent protection layer 500. As shown in FIG. 1, the substrate 100 includes a matrix formed by a plurality of thin film transistors 110 and a plurality of corresponding conductive connection points 120, and the connection points 120 are electrically connected to the TFTs 110. The fluorescent color conversion layer 200 is formed on the bottom surface of the substrate 100, comprising a plurality of fluorescent color conversion patterns 210 formed by red, green, and blue fluorescent color conversion materials, and the black medium 220 formed between the fluorescent color conversion patterns 210. The transparent protection layer 500 is formed on the bottom surface of the fluorescent color conversion layer 200. The UV light conversion layer 300 is composed of the UV electroluminescent material 330, a plurality of electrodes 310 and transparent electrodes 320, wherein the electrode 310 and transparent electrode 320 are formed on the top surface and the bottom surface of the UV light emission layer 300 respectively, so as to excite the UV electroluminescent material 330, to emit light by means of the voltages applied on electrodes 310 and 320. Meanwhile, the transparent electrodes 320 are interleaving formed on the surface of the substrate 100, so that the transparent electrode 320 on the bottom surface of the UV light emission layer 300 is electrically connected to the thin film transistor 110 via the conductive connection point 120. Finally, the encapsulation layer 400 is disposed on the top surface of the UV light emission layer 300, to complete the formation of the bottom emission type full color active OEL structure . . . .

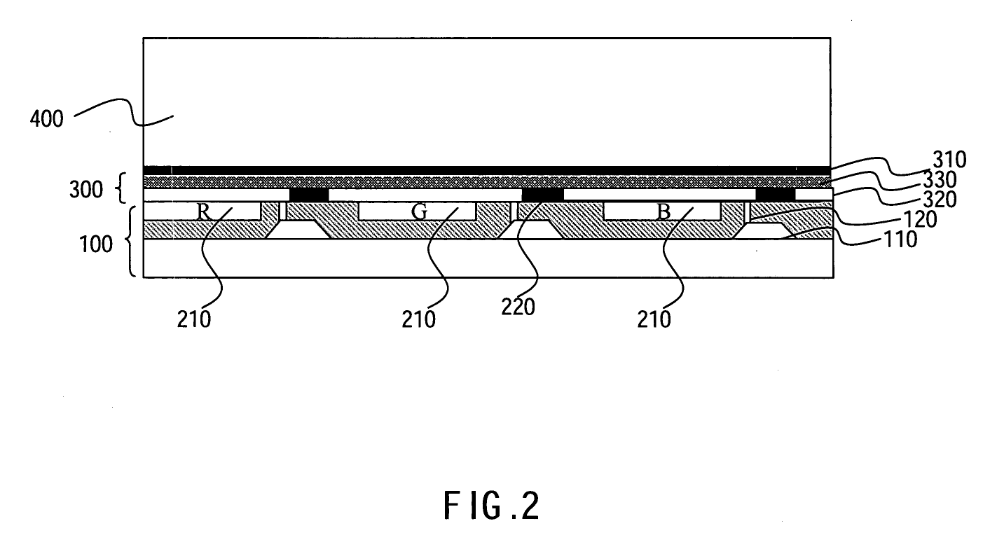

Next, please refer to FIG. 2, which shows the schematic diagram of the OEL structure according to the second embodiment of the invention. In which fluorescent color conversion patterns 210 are directly imbedded into the structure of the substrate 100. To simplify the manufacturing process, the patternization of the fluorescent color conversion layer 200 is performed and completed simultaneously with the substrate 110 during the substrate manufacturing process, so as to form a plurality of fluorescent color conversion patterns 210, which are similar to Color Filters on Array (COA), and are here specifically referred to as Color Changing Medium on Array (CCMOA) process. A black medium 220 is formed between a plurality of transparent electrodes 320 of the UV light emission layer 300, in which the encapsulation layer 400 on top of OEL structure is made of transparent or non-transparent encapsulation material, such as metal, glass or thin film.

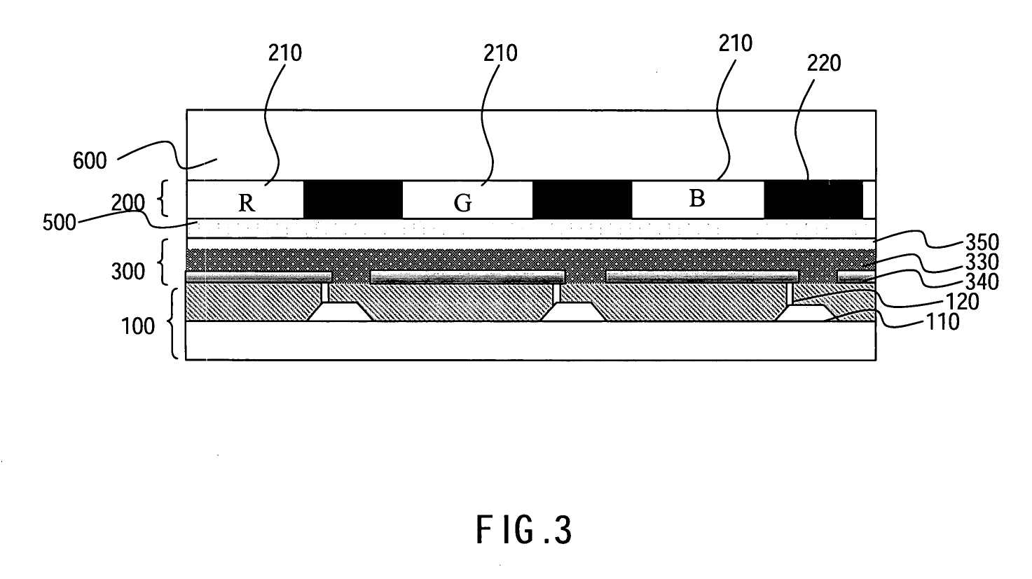

In addition, the invention is provided with a top emission type active organic OEL structure. Please refer to FIG. 3, which shows the schematic diagram of the OEL structure according to the third embodiment of the invention, wherein the above-mentioned fluorescent color conversion layer 200 is provided on top of the UV light emission layer 300, and the second encapsulation layer 600 utilized must be transparent to allow the passage of light. As shown in FIG. 3, the first transparent protection layer 500 is first formed on the top surface of the UV light emission layer 300, and then the fluorescent color conversion layer 200 is formed on the top surface of the first transparent passivation layer 500. In addition, a plurality of reflection electrodes 340 and transparent electrodes 350 are added into the structure of the UV light emission layer 300. The transparent electrode 350 is provided on the top surface of the UV light emission layer 300, and the reflection electrode 340 is provided on the bottom surface of the UV light emission layer 300. The bottom surface of the UV light emission layer 300 is adjacent to and connected to the top surface of the substrate 100, so that a reflection electrode 350 is electrically connected to a thin film transistor 110 via a conductive connection point 120. Based on the above-mentioned structure, the light emitted by UV light emission layer 300 is reflected by the reflection electrode 350 and then transmitted out of the top surface of the UV light emission layer 300, then passing through the fluorescent color conversion layer 200 to be converted into red, green, and blue lights. Finally, the converted light is emitted out through the second transparent encapsulation layer 600, so as to be realized a top emission type OEL structure. Wherein the above-mentioned second transparent encapsulation layer 600 is used as a protection layer and encapsulation layer, and it is preferably made of Diamond Like Carbon (DLC), organic or polymer materials by a thick film or thin film process.

In the above-mentioned embodiment, the black ink or light sensitive polyimide is used as the material of black medium. The fluorescent color conversion layer is made of inorganic or organic fluorescent material. However, the color conversion effect is better for inorganic fluorescent material. The fluorescent color conversion layer is made and formed on the surface of the substrate by means of the Screen Printing, Spraying, Ink Jet Printing or Photolithograph process, or it is made directly into the active matrix substrate structure in the substrate manufacturing process.

The invention being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. An organic electroluminescent display structure, comprising:
a substrate;
a fluorescent color conversion layer, having a plurality of fluorescent color conversion patterns; and
a UV light emission layer, formed on top of the substrate and capable of emitting UV light, which is converted into red, green and blue lights through the fluorescent color conversion layer, and then it is emitted out through the bottom surface of the substrate.

2. The organic electroluminescent display structure of claim 1, wherein the fluorescent color conversion layer is formed in the lower portion of the substrate.

3. The organic electroluminescent display structure of claim 1, wherein the fluorescent color conversion layer is formed and directly imbedded into the substrate.

4. The organic electroluminescent display structure of claim 1, further comprises a encapsulation layer which is coated on a surface of the fluorescent color conversion layer.

5. The organic electroluminescent display structure of claim 4, wherein a material of the encapsulation layer is selected from one group consisted of glass and metal.

6. The organic electroluminescent display structure of claim 1, wherein the fluorescent color conversion layer further comprises a black medium which is formed between the fluorescent color conversion patterns.

7. The organic electroluminescent display structure of claim 6, wherein a material of the black medium is black ink or polyimide.

8. The organic electroluminescent display structure of claim 1, wherein the UV light emission layer includes a UV electroluminescent material.

9. The organic electroluminescent display structure of claim 8, wherein a light emission agitation wavelength of the UV electroluminescent material is under 400 nm.

10. The organic electroluminescent display structure of claim 8, wherein the UV electroluminescent material is selected from one group consisted of a small molecule material, an oligomer and a polymer organic material.

11. The organic electroluminescent display structure of claim 10, wherein when the UV electroluminescent material is the small molecule material, then the UV light emission layer is made of such material by means of the heat evaporation method.

12. An organic electroluminescent display structure, comprising:
a substrate;
a UV light emission layer, formed on top of the substrate; and
a fluorescent color conversion layer, formed on top of the UV light emission layer and includes a plurality of fluorescent color conversion patterns;
wherein, a UV light is emitted by the UV light emission layer, which is converted into red, green, and blue lights through the fluorescent color conversion layer, so as to be realized as top portion light emission.

13. The organic electroluminescent display structure of claim 12, further comprises a transparent encapsulation layer which is coated on a surface of the fluorescent color conversion layer.

14. The organic electroluminescent display structure of claim 13, wherein a material of the transparent encapsulation layer is selected from one group consisted of a diamond like carbon (DLC), an inorganic material, and a polymer material.

15. The organic electroluminescent display structure of 12, wherein the fluorescent color conversion layer includes a black medium which is formed between the fluorescent color conversion patterns.

16. The organic electroluminescent display structure of claim 12, wherein the UV light emission layer includes a UV light electroluminescent material.

17. The organic electroluminescent display structure of claim 16, wherein the UV electroluminescent material is selected from one group consisted of a small molecule material, a oligomer and a polymer organic material.

18. The organic electroluminescent display structure of claim 17, wherein when the UV electroluminescent material is the small molecule material, then the UV light emission layer is made of the material by means of the heat evaporation method.

19. The organic electroluminescent display structure of claim 17, wherein when the UV electroluminescent material is the oligomer or the polymer organic material, then the UV light emission layer is made of the material by means of the Spin Coating or Ink Jet Printing method.

20. The organic electroluminescent display structure of claim 12, wherein the fluorescent color conversion layer is made by means of: Screen Printing, Spraying, Ink Jet Printing or Photolithograph Process.
